(19) United States
(12) Patent Application Publication
(10) Pub. No.: US 2026/0043871 A1
(43) Pub. Date: Feb. 12, 2026

(54) POWER SUPPLY, POWER SUPPLY ANOMALY MANAGEMENT METHOD, DEVICE AND MEDIUM

(71) Applicant: Suzhou MetaBrain Intellegent Technology Co., Ltd., Suzhou, Jiangsu (CN)

(72) Inventor: Yong CHEN, Suzhou, Jiangsu (CN)

(21) Appl. No.: 19/141,128

(22) PCT Filed: Apr. 15, 2024
(86) PCT No.: PCT/CN2024/087798

§ 371 Date: Jun. 19, 2025

(30) Foreign Application Priority Data
Dec. 6, 2023 (CN) 202311659114.2

(51) Int. Cl. G01R 31/40; H02M 1/00; H02M 1/42; H02M 1/44; H02M 3/00; H02M 7/00

(52) U.S. Cl. CPC G01R 31/40; H02M 1/0009; H02M 1/4208; H02M 1/44; H02M 3/003; H02M 7/003

(57) ABSTRACT

Disclosed is a power supply including: a power supply mainboard having a connector slot; a circuit module connected to the power supply mainboard through the connector slot, the circuit module including a detection device configured to send an anomaly signal in response to detecting an anomaly in the circuit module; and a digital management chip connected to the power supply mainboard and configured to, in response to receiving the anomaly signal from the detection device, identify a circuit module corresponding to the detection device that sends the anomaly signal as a faulty circuit module, and send fault information of the faulty circuit module to instruct to replace the faulty circuit module in a connector slot corresponding to the faulty circuit module.

### CROSS-REFERENCE TO RELATED APPLICATION

This application claims priority to Chinese Patent Application No. 202311659114.2, filed on Dec. 6, 2023 in China National Intellectual Property Administration and entitled “Power Supply, Power Supply Anomaly Management Method, Device and Medium”, which is hereby incorporated by reference in its entirety.

### FIELD

The present application relates to the field of electronics technology, and particularly to a power supply, a power supply anomaly management method, a device and a medium.

### BACKGROUND

In related technologies, a design, layout and structural size of each power supply unit (PSU) inside a power supply vary with different power supply power levels, sizes and performance requirements, resulting in significant differences in the designs of power supply units inside different power supplies. Moreover, when any power supply unit inside a power supply becomes abnormal, if an abnormal power supply unit is not handled in time, other power supply units will fail simultaneously. At this time, an entire power supply needs to be replaced, making it difficult to guarantee the production cost, design technology and quality reliability of the power supply.

### SUMMARY

The present application proposes a power supply, a power supply anomaly management method, a device and a medium.

Based on the above objective, a first aspect of embodiments of the present application provides a power supply, including:
a power supply mainboard having connector slots;
circuit modules connected to the power supply mainboard through the connector slots, each circuit module comprising a detection device configured to send an anomaly signal in response to an anomaly detected in the circuit module; and
a digital management chip connected to the power supply mainboard and configured to, in response to the anomaly signal received from the detection device, identify a circuit module corresponding to the detection device that sends the anomaly signal as a faulty circuit module, and send fault information of the faulty circuit module to instruct to replace the faulty circuit module in a connector slot corresponding to the faulty circuit module.

In some implementations, the power supply includes a plurality of connector slots and a plurality of circuit modules connected to the power supply mainboard through the plurality of connector slots, each circuit module including a corresponding detection device, where the digital management chip is further configured to:
monitor whether each circuit module is successively inserted into a corresponding connector slot and/or operating parameters of the plurality of circuit modules are normal via the corresponding detection device;
in response to existence of a circuit module not being successfully inserted into a corresponding connector slot and/or existence of an abnormal operating parameter of a circuit module, send location information of a target circuit module to instruct to adjust the target circuit module, where the target circuit module is a circuit module that is not successfully inserted into a corresponding connector slot and/or has an abnormal operating parameter; and
cut off power supply and wiring signals of the target circuit module in the power supply mainboard.

In some implementations, the power supply further includes: a baseboard management controller, and the digital management chip is further configured to report the location information to the baseboard management controller.

In some implementations, the digital management chip is further configured to:
analyze the operating parameters based on the anomaly signal to obtain an anomaly state; and
report the anomaly state to the baseboard management controller.

In some implementations, the circuit module includes a main power circuit module and a non-main power circuit module, the main power circuit module corresponding to at least two connector slots and the non-main power circuit module corresponding to one connector slot.

In some implementations, the circuit module includes a plurality of main power circuit modules of a same model, and the power supply mainboard includes a plurality of connector slots for connecting the plurality of main power circuit modules of the same model.

In some implementations, the digital management chip is further configured to:
acquire a power demand of the power supply and determine whether the power demand of the power supply exceeds a main power threshold;
in response to the power demand of the power supply not exceeding the main power threshold, instruct to insert one main power circuit module into a corresponding connector slot of the power supply mainboard; and
in response to the power demand of the power supply exceeding the main power threshold, instruct to insert at least two main power circuit modules into corresponding connector slots of the power supply mainboard.

In some implementations, the digital management chip is further configured to:
acquire a power demand of the power supply; and
according the power demand of the power supply, instruct to insert a non-main power circuit module with a power level matching the power demand of the power supply into a corresponding connector slot of the power supply mainboard.

In some implementations, the main power circuit module includes a plurality of circuit modules corresponding to main power functional circuit categories, and the main power functional circuit categories include power factor correction circuits, synchronous rectifier circuits, and auxiliary circuits.

In some implementations, the non-main power circuit module includes a plurality of circuit modules corresponding to non-main power functional circuit categories, and the non-main power functional circuit categories include input fan circuits, electromagnetic interference rectifier circuits, and logic gate circuits.

In some implementations, the operating parameters include operating voltage, operating current, operating power, and operating temperature.

In some implementations, each circuit module includes an independent protection device for disconnecting the circuit module from the power supply mainboard in case of a failure of the circuit module.

In some implementations, the detection device includes at least one of a temperature sensor, a current sensor, a current transformer, and a voltage sensor.

According to another aspect of the present application, a power supply anomaly management method is provided, including:
detecting whether a corresponding circuit module is abnormal by a detection device, where the circuit module is inserted in a connector slot of a power supply mainboard;
in response to an anomaly detected in the corresponding circuit module, triggering the detection device to send an anomaly signal;
in response to a digital management chip receiving the anomaly signal from the detection device, identifying a circuit module corresponding to the detection device that sends the anomaly signal as a faulty circuit module; and
sending fault information of the faulty circuit module by the digital management chip to instruct to replace the faulty circuit module in a connector slot corresponding to the faulty circuit module.

In some implementations, a step of instructing to replace the faulty circuit module in a connector slot corresponding to the faulty circuit module includes:
in response to the faulty circuit module being a main power circuit module and a target circuit module of a same model as the faulty circuit module existing in the power supply mainboard, determining whether operating parameters of the target circuit module are normal;
in response to determining that the operating parameters of the target circuit module are normal, sending, by the digital management chip, a drive signal to cut off power supply and wiring signals between the faulty circuit module and the power supply mainboard, and maintaining normal operation of the power supply through the target circuit module; and
determining a connector slot corresponding to the faulty circuit module based on the fault information, and instructing to replace the faulty circuit module in the corresponding connector slot.

In some implementations, the power supply anomaly management method further includes:
in response to the faulty circuit module being a non-main power circuit module, or in response to the faulty circuit module being a main power circuit module and no target circuit module of a same model as the faulty circuit module existing in the power supply mainboard, determining a connector slot corresponding to the faulty circuit module based on the fault information, and instructing to remove the faulty circuit module from the corresponding connector slot; and
in response to the faulty circuit module being removed, instructing to reinsert a circuit module with a same power level as the faulty circuit module into the corresponding connector slot, whereby the power supply continues to operate.

In some implementations, the power supply anomaly management method further includes:
monitoring, by the digital management chip, whether each circuit module is successively inserted into a corresponding connector slot and/or operating parameters of the plurality of circuit modules are normal via the corresponding detection device;
in response to existence of a circuit module not being successfully inserted into a corresponding connector slot and/or existence of an abnormal operating parameter of a circuit module, sending location information of a target circuit module to instruct to adjust the target circuit module, where the target circuit module is a circuit module that is not successfully inserted into a corresponding connector slot and/or has an abnormal operating parameter; and
cutting off power supply and wiring signals of the circuit module.

In some implementations, the power supply anomaly management method further includes:
in response to a control system receiving the fault information, forwarding the fault information to an equipment room operation and maintenance system to locate the faulty circuit module.

According to yet another aspect of embodiments of the present application, there is further provided a computer device including: at least one processor; and a memory associated with the at least one processor for storing computer-readable instructions that, when read and executed by the at least one processor, implement the steps of the above method.

According to yet another aspect of embodiments of the present application, there is further provided a non-volatile computer-readable storage medium storing computer-readable instructions that, when executed by at least one processor, implement the steps of the above method.

### BRIEF DESCRIPTION OF THE DRAWINGS

To more clearly illustrate the technical solutions in the embodiments of the present application or prior art, the accompanying drawings required for describing the embodiments or prior art will be briefly introduced below. Obviously, the accompanying drawings in the following description are merely some embodiments of the present application, and other embodiments may be obtained by those of ordinary skill in the art according to these drawings without creative efforts.

FIG. 1 is a block diagram of a power supply provided in some embodiments of the present application;

FIG. 2 is a three-dimensional layout diagram of various functional circuits in a power supply according to prior art;

FIG. 3 is a three-dimensional layout diagram of structures of a power supply mainboard and various circuit modules provided in some embodiments of the present application;

FIG. 4 is a schematic diagram of circuit modules inside a power supply provided in some embodiments of the present application;

FIG. 5 is a block diagram of a power supply anomaly management method provided in some embodiments of the present application;

FIG. 6 is a schematic diagram of a power supply anomaly management process provided in some embodiments of the present application;

FIG. 7 is a schematic diagram of a structure of a computer device provided in some embodiments of the present application; and

FIG. 8 is a schematic diagram of a structure of a non-volatile computer-readable storage medium provided in some embodiments of the present application.

### DETAILED DESCRIPTION

To make the objectives, technical solutions, and advantages of the present application clearer, the embodiments of the present application will be further described in detail below with respect to embodiments and with reference to accompanying drawings.

It should be noted that all expressions using “first” and “second” in the embodiments of the present application are intended to distinguish between two different entities or two different parameters with the same name. As may be seen, the terms “first” and “second” are used merely for convenience of description and should not be construed as limiting the embodiments of the present application. Subsequent embodiments will not elaborate on this point.

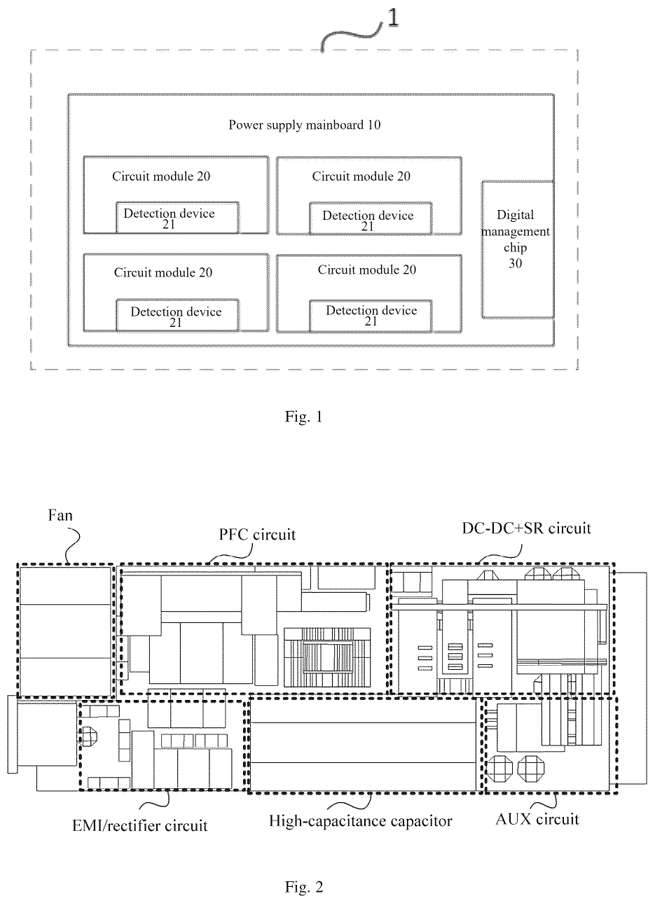

As shown in FIG. 2, in a power supply of related art, each functional circuit is directly soldered to the power supply mainboard according to a layout. Therefore, whenever any issue occurs with the power supply, the entire power supply, including all functional circuits and the power supply mainboard, needs to be replaced. Moreover, the anomaly of one functional circuit inside the power supply will lead to failure of other functional circuits, making it difficult to determine the cause of the power supply anomaly, resulting in increased maintenance costs and reduced maintenance efficiency of the power supply.

Based on the above objective, a first aspect of the embodiments of the present application provides some embodiments of a power supply. As shown in FIG. 1, the power supply 1 includes a power supply mainboard 10, a plurality of circuit modules 20, and a digital management chip 30.

The power supply mainboard 10 has several connector slots. Each circuit module 20 is connected to the power supply mainboard 10 through its corresponding connector slot. Each circuit module 20 includes a corresponding detection device 21. The detection device 21 is configured to send an anomaly signal upon detecting an anomaly in the corresponding circuit module. The digital management chip 30 is connected to the power supply mainboard 10 and is configured to, in response to the anomaly signal received from the detection device 21, identify the circuit module 20 corresponding to the detection device 21 that sent the anomaly signal as the faulty circuit module, and send the fault information of the faulty circuit module to instruct to replace the faulty circuit module in the connector slot corresponding to the faulty circuit module.

In some embodiments, the detection device 21 includes a temperature sensor. Voltage division sampling may be performed on the circuit module 20 through a thermistor and it is determined whether the circuit module 20 is abnormal by detecting the temperature of the circuit module 20. In some embodiments, the detection device 21 includes a current sensor or a current transformer for detecting the current of the circuit module 20. In some embodiments, the detection device 21 includes a voltage sensor. Voltage division sampling by resistors may be performed on the circuit module 20 and it is determined whether an anomaly occurs by detecting the voltage of the circuit module 20. The sampled parameters such as temperature, current, and voltage are transmitted to the digital management chip for processing. The digital management chip may multiply the sampled voltage and current to obtain the power of the circuit module 20. By real-time monitoring of sampled or calculated parameters such as temperature, voltage, current and power, if any parameter exceeds the anomaly threshold set by the digital management chip, the digital management chip may determine that the circuit module 20 is abnormal.

A power supply proposed in the present application includes a power supply motherboard and circuit modules designed according to a set of standards. First of all, a plurality of connector slots are designed on the power supply mainboard, and the power supply units are designed as separate modules, which allows inserting circuit modules of different grades or quantities into the same power supply mainboard's connector slots to obtain power supplies meeting various power demands, improving compatibility and universality of the power supply units. Each circuit module has a detection device that, once a certain individual circuit module is abnormal, immediately disconnects the circuit module from the power supply mainboard, guaranteeing the mainboard and other circuit modules not impacted by the anomaly. Additionally, a digital management chip is added in the power supply mainboard which may monitor operating parameters and connection status of each circuit module in real time and may record anomaly information of the circuit modules, and send the anomaly information to the management system to instruct to replace the circuit module in the connector slot where an abnormal condition occurs in time. Rather than replacing the entire power supply, only the abnormal circuit module needs to be replaced, which enhances maintainability of the overall power supply, saves maintenance costs and improves maintenance efficiency.

In some implementations, the digital management chip is further configured to: monitor whether each circuit module is successfully inserted into its corresponding connector slot and/or whether its operating parameters are normal via the corresponding detection device; in response to any circuit module not being successfully inserted into its corresponding connector slot and/or any abnormal operating parameter for circuit modules, send location information of a target circuit module to instruct to adjust the target circuit module, where the target circuit module is a circuit module that is not successfully inserted into the corresponding connector slot and/or has an abnormal operating parameter; and cut off power supply and wiring signals of the target circuit module in the power supply mainboard.

With the power supply provided in the present application, troubleshooting efficiency of the power supply is improved and normal powering by the power supply is guaranteed by disposing a digital management chip on the power supply mainboard to manage and monitor circuit modules, quickly locate faulty circuit modules upon failure or anomaly, and inform the user to replace the faulty power supply units in the corresponding connector slots.

In some implementations, the circuit module includes a main power circuit module and a non-main power circuit module, the main power circuit module corresponding to at least two connector slots and the non-main power circuit module corresponding to one connector slot.

In some implementations, the main power circuit module includes a plurality of circuit modules corresponding to main power functional circuit categories, and the main power functional circuit categories include power factor correction circuits, synchronous rectifier circuits, and auxiliary circuits.

In some implementations, the non-main power circuit module includes a plurality of circuit modules corresponding to non-main power functional circuit categories, and the non-main power functional circuit categories include input fan circuits, electromagnetic interference rectifier circuits, and logic gate circuits.

In some implementations, the main power circuit modules correspond to the primary functional circuits in the power supply, which contain the most power devices and are most prone to anomalies. The main power circuit modules primarily include a PFC (Power Factor Correction) circuit module, a DC-DC+SR (Synchronous Rectification) circuit module, and an AUX (Auxiliary) circuit module. An N+M module redundancy is implemented for the main power circuit modules, where N and M are positive integers. For example, a 1+1 redundancy may be adopted in the PFC circuit modules. Under normal conditions, two PFC circuit modules may operate simultaneously. When an abnormal condition occurs in PFC circuit module 1, the digital management chip actively cuts off the power supply and corresponding power supply wiring signals for PFC circuit module 1 to isolate PFC circuit module 1. However, since PFC circuit module 2 remains in normal operation, the abnormal condition of PFC circuit module 1 will not affect the overall operation of the power supply. Therefore, there may be a plurality of connector slots for the main power circuit modules of the same model in the power supply mainboard for connecting a plurality of main power circuit modules of the same model. Similarly, a 1+2 redundancy or the like may be used for the main power circuit modules. The N+M module redundancy may be designed according to the actual application situation, and the number of N+M module redundancy is not limited here.

In some implementations, for the non-main power circuit modules, since the failure probability is low, redundant design is not required from the perspective of design layout and cost. Therefore, the non-main power circuit modules and the connector slots therefor have a one-to-one correspondence relationship.

In some implementations, the digital management chip is further configured to: obtain the power demand of the power supply and determine whether the power demand exceeds a main power threshold; in response to the power demand not exceeding the main power threshold, instruct to insert one main power circuit module into the corresponding connector slot of the power supply mainboard; and in response to the power demand exceeding the main power threshold, instruct to insert at least two main power circuit modules into the corresponding connector slots of the power supply mainboard.

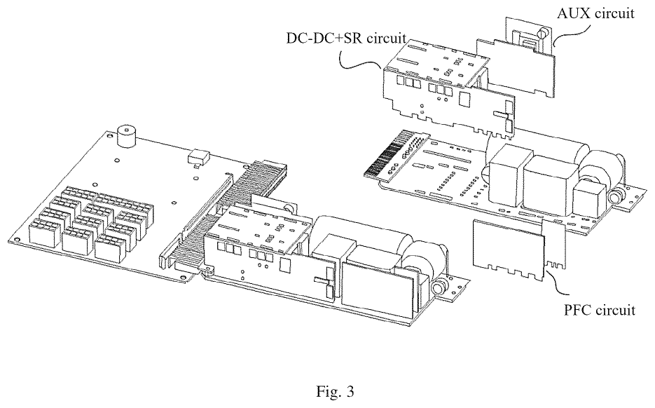

FIG. 3 is a three-dimensional layout diagram of structures of a power supply mainboard and circuit modules provided in some embodiments of the present application.

In an example, taking a CRPS (Common Redundant Power Supply, a server power supply of standard architecture) standard power supply with a size of 185 mm*73.5 mm*40 mm as an example, in the case where the power supply mainboard has been fixed, corresponding connector slots are reserved on the power supply mainboard for various functional circuits. Because the PFC circuits, DC-DC+SR circuits and AUX circuits are the main power circuits in the power supply, at least 2 connector slots need to be reserved for each of the PFC circuit, DC-DC+SR circuit and AUX circuit on the power supply mainboard. For example, 2-3 connector slots may be reserved to implement N+M module redundancy for the main power circuit module, as shown in FIG. 3.

With the power supply provided in the present application, by disposing reserved connector slots on the power supply mainboard, the modularized power supply units are combined with the connector slots of the power supply mainboard to realize flexible replacement of circuits of the power supply, which facilitates timely maintenance of the power supply. And reserving multiple connector slots for the main power circuit modules allows implementing redundancy and expansion of the main power circuit modules according to different power demands for the power supply.

In some implementations, the digital management chip is further configured to: obtain the power demand of the power supply and instruct to insert non-main power circuit modules with power levels matching power demand of the power supply into the corresponding connector slots of the power supply mainboard according to the power demand of the power supply.

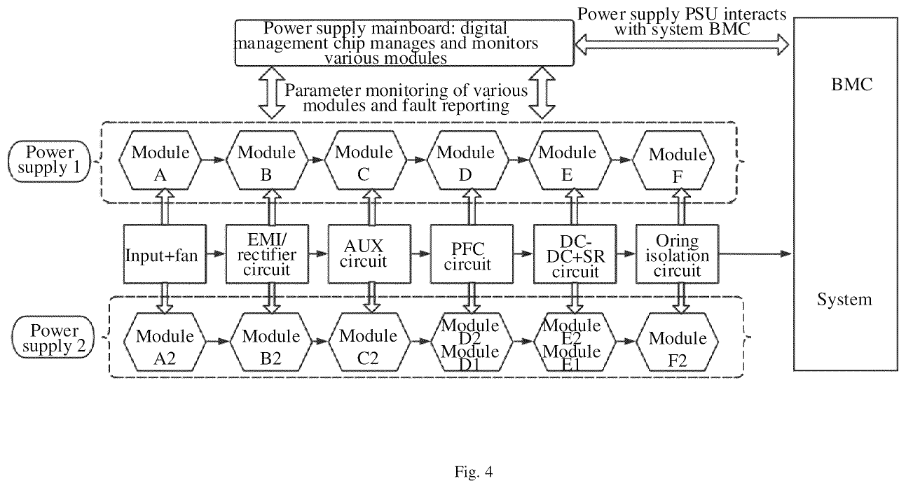

FIG. 4 is a schematic diagram of some embodiments of circuit modules inside the power supply provided in the present application. As shown in FIG. 4, circuit modules with power levels corresponding to different performance demands are provided for different functional circuits. Circuit module A corresponds to the input circuit and fan circuit. The input circuit in circuit module A supports C14 plug power supply cord and C20 plug power supply cord, and the fan supports speeds from 18,000 rpm to 35,000 rpm. Among them, the C14 plug power supply line is generally used to connect computers, various household appliances and office devices, etc. The C20 plug power supply line may output higher power and is more suitable for fields such as large servers, workstations and PDU (Power Distribution Unit) sockets and etc. Circuit module B corresponds to EMI (Electromagnetic Interference) circuits or rectifier circuits and supports Class A (industrial grade) and Class B (civilian grade). Circuit module C corresponds to the auxiliary standby output circuit. Circuit module C supports 10 W-60 W auxiliary output demands and is a low-power circuit module. Circuit module D corresponds to PFC circuits, including traditional APFC (Active Power Factor Correction) circuits, bridgeless PFC circuits and totem PFC circuits. Circuit module D may support 800-2000 W power demands under high input voltages. Circuit module E corresponds to DC-DC-SR circuits. Circuit module E may support 800-1800 W power demands under high input voltages. Circuit module F corresponds to Oring (logic gate) circuits. Among them, circuit module A, circuit module B, and circuit module F are non-main power circuit modules, and circuit module C, circuit module D, and circuit module E are main power circuit modules.

In an example, circuit module A and circuit module A2 are non-main power circuit modules corresponding to the same functional circuits with different power levels, respectively. For example, the power level of circuit module A is such that the input circuit supports C14 or the fan speed supports 18,000 rpm, and the power level of circuit module A2 is such that the input circuit supports C20 or the fan speed supports 35,000 rpm. Similarly, circuit modules B and B2, circuit modules C and C2, and circuit modules F and F2 are also non-main power circuit modules corresponding to the same functional circuits with different power levels, respectively, and circuit modules D, D1 and D2, and circuit modules E, E1 and E2 are main power circuit modules corresponding to the same functional circuits with different power levels, respectively, as shown in FIG. 4. Further, according to the power demand, two or more main power circuit modules with the same power level may be selected for redundancy, or two or more main power circuit modules with different power levels may be selected for redundancy.

In an example, if there is a power demand of 800 W, it is necessary to insert one circuit module with a corresponding function and a power level into the connector slot corresponding to each functional circuit on the power supply mainboard, as shown in the power supply 1 in FIG. 4. If there is a power demand of 2400 W, then one non-main power circuit module with a corresponding function and a power level is inserted into each of the connector slots corresponding to the non-main power functional circuits on the power supply mainboard, and two main power circuit modules with corresponding functions are inserted into the connector slots corresponding to the main power functional circuits, that is, two PFC circuit modules supporting 800-2000 W and two DC-DC+SR circuit modules supporting 800-1800 W are inserted to match the power demand of 2400 W, as shown in the power supply 2 in FIG. 4. It should be noted that the power levels involved in the present embodiments are for illustration, and should not be construed as a limitation on the solution of the present application. The power level design may be flexibly configured according to business scenarios during implementation.

According to the power supply provided in the present application, after the required power demand is determined, the power supply meeting the demand may be obtained by simply inserting circuit modules of corresponding grades and functions into the power supply mainboard, without the need to design separate power supplies for different power demands or performances. Furthermore, all functional circuits are modularized, and circuit modules of corresponding power levels are provided for different power demands, thereby significantly improving the compatibility and versatility of power supply units. By simply combining or replacing circuit modules, the same functional circuit modules may be universally used across different power supplies, enhancing the flexibility of power supply variation and facilitating subsequent maintenance of the power supply.

In some implementations, the operating parameters include operating voltage, operating current, operating power, and operating temperature.

In some implementations, the digital management chip transmits wiring signals to and supplies power to various circuit modules via the control circuit. The detection device acquires operating parameters such as operating voltage, operating current, operating power, and operating temperature via the corresponding circuit module in real time. Once any operating parameter does not meet the normal operating range corresponding to the power demand of the power supply, the detection device sends an anomaly signal via the control circuit. The digital management chip detects the anomaly signal via the control circuit and immediately triggers a drive signal to turn off the power switch corresponding to the faulty circuit module, thereby disconnecting the control circuit of the faulty circuit module and the power supply mainboard. While detecting the anomaly signal, the digital management chip also retrieves the operating parameters of the corresponding circuit module from the detection device to analyze the corresponding anomaly condition, such as a voltage below the normal operating range or a temperature above the normal operating range, and then reports the location and the anomaly condition of the circuit module to the BMC connected to the power supply, enabling users to identify the cause and the location of the power supply fault based on the reported anomaly condition.

In some implementations, each circuit module includes an independent protection device for disconnecting the circuit module from the power supply mainboard in case of a failure of the circuit module.

In an example, the protection device may be a fuse. Each circuit unit is equipped with an independent fuse. If any individual circuit module fails instantaneously due to short circuit, the fuse may immediately blow, without causing failure of the power supply mainboard and other circuit modules.

In some implementations, in case of instantaneous failure due to short circuit of a power device in a circuit module, in order to avoid the situation in which the digital management chip fails to, in a short period, control the power supply switch corresponding to the circuit module in the power supply mainboard to turn off so as to cut off powering for the circuit module, the protection device may promptly detect the temperature change during short circuit and trigger blowing, enabling the circuit module to disconnect from the power supply mainboard autonomously. This guarantees that the short circuit of the circuit module will not influence other circuit modules in the power supply, thereby avoiding concurrent failure of other circuit modules. The digital management chip, combined with the independent fuse inside each circuit module, achieves dual protection for the power supply.

A power supply proposed in the present application includes a power supply motherboard and circuit modules designed according to a set of standards. First of all, a plurality of connector slots are designed on the power supply mainboard, and the power supply units are designed as separate modules, which allows inserting circuit modules of different grades or quantities into the power supply mainboard's connector slots to obtain power supplies meeting various power demands, effectively improving compatibility and universality of the power supply units. Each circuit module has a detection device that, when any one individual circuit module is abnormal, immediately disconnects the abnormal circuit module from the power supply mainboard, guaranteeing the mainboard and other circuit modules not impacted by the anomaly. Additionally, a digital management chip is added in the power supply mainboard which may monitor operating parameters and connection status of each circuit module in real time and may record anomaly information of the circuit modules, and send it to the management system to instruct to replace the circuit module in the connector slot where an abnormal condition occurs in time. Rather than replacing the entire power supply, only the abnormal circuit module needs to be replaced, which enhances maintainability of the overall power supply, saves maintenance costs and improves maintenance efficiency.

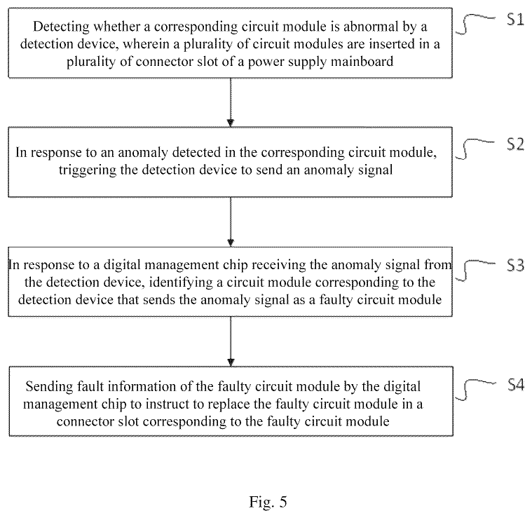

As shown in FIG. 5, another aspect of the present application further provides a power supply anomaly management method, including the following steps.

Step S1, detecting whether a corresponding circuit module is abnormal by a detection device, where a plurality of circuit modules are inserted into a plurality of connector slots of a power supply mainboard.

Step S2, in response to an anomaly detected in the corresponding circuit module, triggering the detection device to send an anomaly signal.

Step S3, in response to a digital management chip receiving the anomaly signal from the detection device, identifying a circuit module corresponding to the detection device that sends the anomaly signal as a faulty circuit module.

Step S4, sending fault information of the faulty circuit module by the digital management chip to instruct to replace the faulty circuit module in a connector slot corresponding to the faulty circuit module.

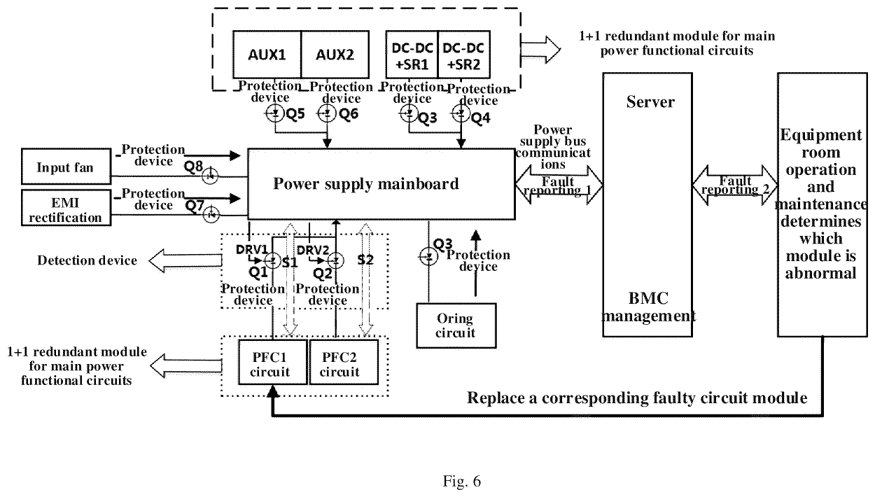

FIG. 6 is a schematic diagram of a power supply anomaly management process provided in some embodiments of the present application.

In an example, a PFC circuit is used as an example to illustrate the anomaly management process of a power supply. As the PFC circuit belongs to the main power functional circuit category, the power supply mainboard reserves connector slots corresponding to 2-3 PFC circuit modules to facilitate module redundancy and power expansion. As shown in FIG. 6, during normal power supply operation, the PFC1 circuit module and the PFC2 circuit module operate in parallel without interference. The digital management chip on the power supply mainboard monitors through path S1 and path S2 whether the corresponding PFC1 circuit module and the PFC2 circuit module are successfully inserted into the connector slots and/or whether the operating parameters are abnormal, respectively. If an anomaly occurs in the PFC1 circuit module, the digital management chip detects it through path S1 and immediately triggers the DRV1 (drive signal) signal to turn off the power switch Q1, disconnecting the control circuit of the PFC1 circuit module from the power supply mainboard. In case of instantaneous failure caused by short circuit of a power device in the PFC1 circuit module, since the control circuit of the power supply mainboard may not be disconnected in a short period, a fuse is used to directly cut off the protection of the PFC1 circuit module, preventing PFC1 from affecting other circuit modules. Since the PFC2 circuit module remains in normal operation, the power supply does not shut down and continues stable powering operation. Meanwhile, the digital management chip has recorded fault information of the PFC1 circuit module and reports it to the Baseboard Management Controller (BMC) system.

Furthermore, as the power supply continues powering, the BMC system forwards the fault information to the equipment room operation and maintenance system. When the PFC2 circuit module also malfunctions, its control circuit is similarly disconnected from the power supply mainboard such that other circuit modules remain unaffected by the PFC functional circuit failure. If both PFC functional circuits fail, causing power supply shutdown, the digital management chip reports fault information of the PFC2 circuit module to the BMC system, which forwards the fault information to the equipment room operation and maintenance system to instruct maintenance personnel to identify the faulty location based on location information in the fault information and replace the PFC circuit modules for the power supply.

The power supply anomaly management method provided in the present application improves fault localization accuracy for power supply failure and maintenance efficiency of equipment room operation and maintenance personnel while reducing power supply replacement costs.

In some implementations, a step of instructing to replace the faulty circuit module in a connector slot corresponding to the faulty circuit module includes: in response to the faulty circuit module being a main power circuit module and a target circuit module of a same model as the faulty circuit module existing in the power supply mainboard, determining whether operating parameters of the target circuit module are normal; in response to determining that the operating parameters of the target circuit module are normal, sending, by the digital management chip, a drive signal to cut off power supply and wiring signals between the faulty circuit module and the power supply mainboard, and maintaining normal operation of the power supply through the target circuit module; and determining the connector slot corresponding to the faulty circuit module based on the fault information, and instructing to replace the faulty circuit module in the corresponding connector slot.

In some implementations, the power supply anomaly management method of the present application further includes: in response to the faulty circuit module being a non-main power circuit module, or in response to the faulty circuit module being a main power circuit module and no target circuit module of a same model as the faulty circuit module existing in the power supply mainboard, determining a connector slot corresponding to the faulty circuit module based on the fault information, and instructing to remove the faulty circuit module from the corresponding connector slot; and in response to the faulty circuit module being removed, instructing to reinsert a circuit module with a same power level as the faulty circuit module into the corresponding connector slot, whereby the power supply continues to operate.

In some implementations, the power supply anomaly management method of the present application further includes: monitoring, by the digital management chip, whether each circuit module is successfully inserted into the corresponding connector slot and/or whether the operating parameters of several circuit modules are normal via the detection device; in response to the existence of a circuit module not being successfully inserted into the corresponding connector slot and/or the existence of an abnormal operating parameter of a circuit module, sending location information of a target circuit module to instruct to adjust the target circuit module, where the target circuit module is a circuit module that is not successfully inserted into a corresponding connector slot and/or has an abnormal operating parameter; and cutting off power supply and wiring signals of the target circuit module.

In some implementations, the power supply anomaly management method of the present application further includes: in response to the control system receiving the fault information, forwarding the fault information to the equipment room operation and maintenance system to locate the faulty circuit module.

The power supply anomaly management method provided in the present application obtains abnormalities of circuit modules in time via the detection device in each circuit module. Once an anomaly occurs in any individual circuit module, the detection device immediately disconnects the circuit module from the power supply mainboard, ensuring the power supply mainboard and other circuit modules remain unaffected by the anomaly. Additionally, a digital management chip is added in the power supply mainboard which may monitor operating parameters and connection status of each circuit module in real time and may record anomaly information of the circuit modules, and send anomaly information to the management system to instruct to replace the circuit module in the connector slot where an abnormal condition occurs in time. Rather than replacing the entire power supply, only the abnormal circuit module needs to be replaced, which enhances maintainability of the overall power supply, saves maintenance costs and improves maintenance efficiency.

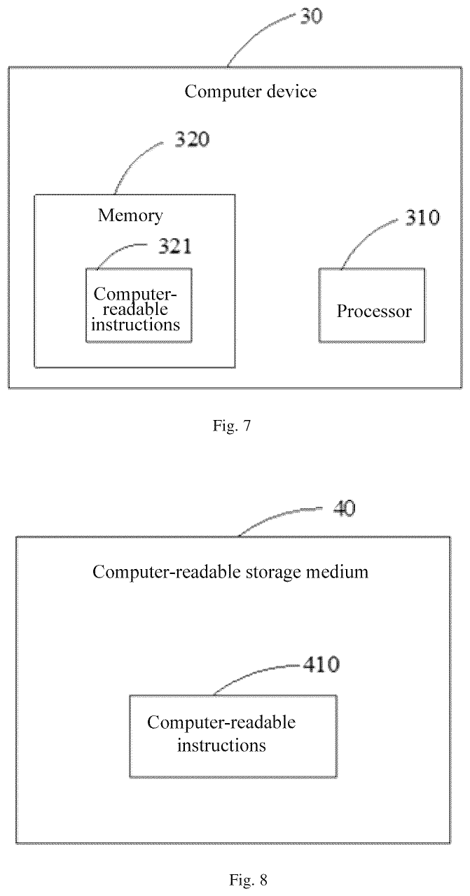

Based on the same inventive concept, according to another aspect of the present application, and as shown in FIG. 7, some embodiments of the present application further provides a computer device 30 including at least one processor 310 and a memory 320 storing computer-readable instructions 321 that, when read and executed by the processor 310, implement the steps of the aforementioned method.

Based on the same inventive concept, according to another aspect of the present application, as shown in FIG. 8, some embodiments of the present application further provide a non-volatile computer-readable storage medium 40 storing computer-readable instructions 410 that, when executed by a processor, implement the aforementioned method.

Finally, it should be noted that, as may be appreciated by one of ordinary skill in the art, the processes in the method according to the above-described embodiments may be fully or partially implemented by instructing hardware with computer-readable instructions. A program may be stored in a computer-readable storage medium that, when executed, may include the processes according to the embodiments of the above-described method. The storage medium of the program may be a magnetic disk, an optical disk, a read-only memory (ROM), or a random access memory (RAM), or the like. The above-described embodiments of the computer-readable instructions may achieve the same or similar effects as the corresponding embodiments of any of the above-described methods.

Those skilled in the art will also appreciate that the various exemplary logic blocks, modules, circuits, and algorithmic steps described in connection with the disclosure herein may be implemented as electronic hardware, computer software, or a combination of both. To clearly illustrate this interchangeability of hardware and software, various illustrative components, blocks, modules, circuits, and steps have been described generally in terms of their functionality. Whether such functionality is implemented as software or hardware depends upon the specific application and design constraints imposed on the overall system. Those skilled in the art may implement the described functionality in varying ways for each particular application, but such implementations should not in no way be interpreted as causing a departure from the scope of the embodiments disclosed in the present application.

The above are exemplary embodiments disclosed in the present application. But it should be noted that various changes and modifications may be made without departing from the scope of the disclosed embodiments as defined by the claims. The functions, steps, and/or actions in the method claims according to the disclosed embodiments described herein need not be performed in any particular order. The sequence numbers of the embodiments disclosed above are for description only and do not represent the superiority or inferiority of the embodiments. Furthermore, although elements disclosed in the embodiments of the present application may be described or claimed in individual form, they may also be understood as plural unless explicitly limited to singular.

It should be understood that, as used herein, the singular forms “a” and “an” are intended to include the plural forms as well, unless the context clearly indicates otherwise. It should also be understood that the term “and/or” as used herein refers to any and all possible combinations of one or more of the items listed above in association.

Those of ordinary skill in the art should understand that the discussion of any embodiments above is exemplary only and is not intended to imply that the scope of the disclosed embodiments (including the claims) of the present application is limited to these examples. Under the concept of the present application, technical features in the above embodiments or different embodiments may also be combined, and there exist many other variations in different aspects of embodiments of the present application as described above, which are not provided in detail for brevity. Therefore, any omissions, modifications, equivalent substitutions, improvements, etc. made within the spirit and principles of embodiments of the present application shall be encompassed within the protection scope of embodiments of the present application.

1. A power supply, comprising:
a power supply mainboard, the power supply mainboard comprising one or more a connector slots;
one or a circuit modules connected to the power supply mainboard through each connector slot, each circuit module comprising a corresponding detection device, the detection device configured to send an anomaly signal in response to an anomaly detected in a corresponding circuit module; and
a digital management chip connected to the power supply mainboard, the digital management chip configured to, in response to the anomaly signal received from the detection device, identify the circuit module corresponding to the detection device that sends the anomaly signal as a faulty circuit module, and send fault information of the faulty circuit module to instruct to replace the faulty circuit module in a connector slot corresponding to the faulty circuit module;
wherein the digital management chip is further configured to:
monitor whether each circuit module is successively inserted into a corresponding connector slot and/or whether operating parameters of each circuit module are normal via the corresponding detection device;
in response to existence of a circuit module not being successfully inserted into the corresponding connector slot and/or existence of an abnormal operating parameter of a circuit module, send location information of a target circuit module to instruct to adjust the target circuit module; and
cut off power supply and wiring signals of the target circuit module in the power supply mainboard.

2. The power supply of claim 1,
wherein the target circuit module is a circuit module of the one or more circuit modules that is not successfully inserted into the corresponding connector slot and/or has the abnormal operating parameter.

3. The power supply of claim 2, wherein the power supply further comprises: a baseboard management controller, and the digital management chip is further configured to report the location information to the baseboard management controller.

4. The power supply of claim 3, wherein the digital management chip is further configured to:
analyze the operating parameters based on the anomaly signal to obtain an anomaly state; and
report the anomaly state to the baseboard management controller.

5. The power supply of claim 1, wherein each of the one or more circuit modules comprises a main power circuit module and a non-main power circuit module, the main power circuit module corresponding to at least two connector slots of the one or more connector slots, and the non-main power circuit module corresponding to one connector slot of the one or more connector slots.

6. The power supply of claim 5, wherein each of the one or more circuit modules comprises a plurality of main power circuit modules of a same model, and the power supply mainboard comprises a plurality of connector slots for connecting the plurality of main power circuit modules of the same model.

7. The power supply of claim 5, wherein the digital management chip is further configured to:
acquire a power demand of the power supply and determine whether the power demand of the power supply exceeds a main power threshold;
in response to the power demand of the power supply not exceeding the main power threshold, instruct to insert one main power circuit module into a corresponding connector slot of the power supply mainboard; and
in response to the power demand of the power supply exceeding the main power threshold, instruct to insert at least two main power circuit modules into corresponding connector slots of the power supply mainboard.

8. The power supply of claim 5, wherein the digital management chip is further configured to:
acquire a power demand of the power supply; and
according to the power demand of the power supply, instruct to insert a non-main power circuit module with a power level matching the power demand of the power supply into a corresponding connector slot of the power supply mainboard.

9. The power supply of claim 5, wherein the main power circuit module comprises a plurality of circuit modules corresponding to main power functional circuit categories, and the main power functional circuit categories comprise power factor correction circuits, synchronous rectifier circuits, and auxiliary circuits.

10. The power supply of claim 5, wherein the non-main power circuit module comprises a plurality of circuit modules corresponding to non-main power functional circuit categories, and the non-main power functional circuit categories comprise input fan circuits, electromagnetic interference rectifier circuits, and logic gate circuits.

11. The power supply of claim 1, wherein the operating parameters comprise operating voltage, operating current, operating power and operating temperature.

12. The power supply of claim 1, wherein each of the one or more circuit modules comprises an independent protection device for disconnecting each of the one or more circuit modules from the power supply mainboard in case of a failure of the corresponding circuit module.

13. The power supply of claim 1, wherein the detection device comprises at least one of a temperature sensor, a current sensor, a current transformer, or a voltage sensor.

14. A power supply anomaly management method, comprising:
detecting whether a corresponding circuit module is abnormal by a detection device, wherein the circuit module is inserted in one or more connector slots of a power supply mainboard;
in response to an anomaly detected in the corresponding circuit module, triggering a corresponding detection device to send an anomaly signal;
in response to a digital management chip receiving the anomaly signal sent by a detection device, identifying a circuit module corresponding to the detection device that sends the anomaly signal as a faulty circuit module; and
sending fault information of the faulty circuit module by the digital management chip to instruct to replace the faulty circuit module in a connector slot corresponding to the faulty circuit module;
wherein the power supply anomaly management method further comprises:
monitoring, by the digital management chip, whether each circuit module is successively inserted into a corresponding connector slot and/or whether operating parameters of each circuit module are normal via the detection device;
in response to existence of a circuit module not being successfully inserted into a corresponding connector slot and/or existence of an abnormal operating parameter of a circuit module, sending location information of a target circuit module to instruct to adjust the target circuit module; and
cutting off power supply and wiring signals of the target circuit module.

15. The power supply anomaly management method of claim 14, wherein a step of instructing to replace the faulty circuit module in a connector slot corresponding to the faulty circuit module comprises:
in response to the faulty circuit module being a main power circuit module and a target circuit module of a same model as the faulty circuit module existing in the power supply mainboard, determining whether operating parameters of the target circuit module are normal;
in response to determining that the operating parameters of the target circuit module are normal, sending, by the digital management chip, a drive signal to cut off the power supply and wiring signals between the faulty circuit module and the power supply mainboard, and maintaining normal operation of the power supply through the target circuit module; and
determining the connector slot corresponding to the faulty circuit module based on the fault information, and instructing to replace the faulty circuit module in the corresponding connector slot.

16. The power supply anomaly management method of claim 15, further comprising:
in response to the faulty circuit module being a non-main power circuit module, or in response to the faulty circuit module being the main power circuit module and no target circuit module of a same model as the faulty circuit module existing in the power supply mainboard, determining the connector slot corresponding to the faulty circuit module based on the fault information, and instructing to remove the faulty circuit module from the corresponding connector slot; and
in response to the faulty circuit module being removed, instructing to reinsert a circuit module with a same power level as the faulty circuit module into the corresponding connector slot, whereby the power supply continues to operate.

17. The power supply anomaly management method of claim 14,
wherein the target circuit module is a circuit module that is not successfully inserted into a corresponding connector slot and/or has the abnormal operating parameter.

18. The power supply anomaly management method of claim 14, further comprising:
in response to a control system receiving the fault information, forwarding the fault information to an equipment room operation and maintenance system to locate the faulty circuit module.

19. A computer device, comprising:
at least one processor; and
a memory storing a computer program executable on the processor, the processor executes steps of a power supply anomaly management method when executing the computer program, the power supply anomaly management method comprising:
detecting whether a corresponding circuit module is abnormal by a detection device, wherein the circuit module is inserted in one or more connector slots of a power supply mainboard;
in response to an anomaly detected in the corresponding circuit module, triggering a corresponding detection device to send an anomaly signal;
in response to a digital management chip receiving the anomaly signal sent by a detection device, identifying a circuit module corresponding to the detection device that sends the anomaly signal as a faulty circuit module; and
sending fault information of the faulty circuit module by the digital management chip to instruct to replace the faulty circuit module in a connector slot corresponding to the faulty circuit module;
wherein the power supply anomaly management method further comprises:
monitoring, by the digital management chip, whether each circuit module is successively inserted into a corresponding connector slot and/or whether operating parameters of each circuit module are normal via the detection device;
in response to existence of a circuit module not being successfully inserted into a corresponding connector slot and/or existence of an abnormal operating parameter of a circuit module, sending location information of a target circuit module to instruct to adjust the target circuit module; and
cutting off power supply and wiring signals of the target circuit module.

20. (canceled)

21. The power supply of claim 12, wherein the independent protection device is a fuse, and each of the one or more circuit modules is disposed with an independent fuse.
